(19) United States
(12) Patent Application Publication
(10) Pub. No.: US 2010/0024445 A1
(43) Pub. Date: Feb. 4, 2010

(54) SIMULTANEOUSLY PROVIDING RENEWABLE POWER AND COOLING FOR DATA CENTER OPERATION

(76) Inventor: J. Edward Cichanowicz, Saratoga, CA (US)

Correspondence Address: ROBERT K. CARPENTER, 5 PIPESTEM COURT, ROCKVILLE, MD, 20854, US

(21) Appl. No.: 12/535,658

(22) Filed: Aug. 4, 2009

Related U.S. Application Data
(60) Provisional application No. 61/085,908, filed on Aug. 4, 2008.

(51) Int. Cl. F25B 9/00; F25D 23/00; H05K 7/20

(52) U.S. Cl. 62/86; 62/259.2

(57) ABSTRACT

A method of cooling a data center can include: extracting compressed air from a storage vessel or process stream, expanding the air to lower a pressure of the air, with the ratio of the pressure of air after expansion to the pressure of air before expansion being the critical pressure ratio, defining choked flow, providing a constant mass rate of cooling air, thus lowering a temperature of the air; and dispersing the expanded air through a heat sink onto a microprocessor or other heat generating component of a server or a storage device, thus cooling the microprocessor or the other heat generating component of the server or the storage device.

### CROSS-REFERENCE TO RELATED APPLICATIONS

This application claims the benefit of U.S. Provisional Application No. 61/085,908, filed Aug. 4, 2008, which is hereby incorporated herein by reference in its entirety.

### STATEMENT REGARDING FEDERALLY SPONSORED RESEARCH OR DEVELOPMENT

(Not Applicable)

### THE NAMES OF THE PARTY TO A JOINT RESEARCH AGREEMENT

(Not Applicable)

### INCORPORATION-BY-REFERENCE OF MATERIAL SUBMITTED ON A COMPACT DISC

(Not Applicable)

### BACKGROUND OF THE INVENTION

(1) Field of the Invention

This disclosure is directed to methods, systems, and apparatuses for simultaneously providing renewable power and cooling for data center operation.

(2) Description of Related Art Including Information Submitted under 37 CFR 1.97 and 1.98

It was highlighted in an August 2007 report to Congress by the U.S. Environmental Protection Agency (EPA, 2007) that datacenter power consumption is rapidly growing, and will continue to do so.

Compressed air energy storage (CAES) systems have been used in Germany and Alabama to provide peak-shaving services, in that low cost baseload power (such as generated from coal or nuclear plants) is stored and applied for peaking duty. Specifically, at the McIntosh plant in Alabama, low cost baseload power is used to charge an underground reservoir with high pressure air during periods of time throughout the day when excess, or lower cost, power is available. During times of peak load, such as early to mid morning hours, the high pressure air is passed through an expansion turbine to generate power. Heat is added during the expansion process in the form of burning natural gas fuel, to improve the overall thermal efficiency of the process, and increase the power output. In this manner, CAES is used to store power, enabling available, relatively low cost baseload power to be used to meet peak power demands.

### BRIEF SUMMARY OF THE INVENTION

At least some aspects and/or embodiments of this disclosure are directed to a method of cooling a data center, including: extracting compressed air from a storage vessel or process stream, expanding the air to lower a pressure of the air, with the ratio of a pressure of the air after expansion to the pressure of air before expansion being the critical pressure ratio, defining choked flow, providing a constant mass rate of cooling air, thus lowering a temperature of the air; and dispersing the expanded air through a heat sink onto a microprocessor or other heat generating component of a server or a storage device, thus cooling the microprocessor or the other heat generating component of the server or the storage device. In at least some embodiments, the compressed air is extracted from a compressed air energy storage vessel. In at least some embodiments, a ratio of the pressure to which the air is expanded, compared to delivery pressure prior to expansion, is equal to a critical pressure defining choked flow, and thereby expansion is at a ratio to provide choked flow, thereby providing a temperature of expanded cooling media to the device being cooled, of from 0° F. to 90° F., and providing a constant mass rate of cooling air. In at least some embodiments, the cooling air after expansion is retained separate from ambient air within a sheath or plenum that encompasses a component being cooled, thus eliminating cooling air bypass or leakage from the heat sink, with such cooling air subsequently discharged. In at least some embodiments, the effluent air from the cooling sheath or plenum located on the component is at a temperature of 90° F. or less and provides cooling for other of a server or storage device components, and is directed to a central evacuation chamber, and is thereafter removed from the data center. In at least some embodiments, waste heat contained in the air after providing for cooling of the various components of a server or data center, is applied to provide for preheat of stored air after expansion and preceding an inlet of an expansion turbine of a compressed air energy storage system.

At least some aspects and/or embodiments of this disclosure are directed to a method of cooling a data center, including: extracting a stream of high pressure air stored within a reservoir for a compressed air energy storage (CAES) system, reducing pressure of the air to near atmospheric and lowering the temperature, and passing the air at a temperature of between 0° F. and 80° F. through a heat exchanger that is configured to remove heat from a data center, the stream of air thereafter containing data center waste heat that is returned to the inlet of the expansion turbine. In at least some embodiments, the method further comprises: providing an expansion of cooling air from the CAES reservoir such that a ratio of air pressure after expansion to the pressure before expansion is a critical pressure ratio to establish choked flow and to provide cooling of the data center, said stream of cooling air thereafter containing data center waste heat that is returned to the inlet of the expansion turbine.

At least some aspects and/or embodiments of this disclosure are directed to a method of utilizing waste heat from a data center, including: deploying the waste heat from the data center to preheat expanded gas extracted from a compressed air energy storage (CAES) reservoir prior to introduction to an expansion turbine within a CAES generating system, so as to utilize the waste heat from the data center to increase efficiency or output of an expansion turbine in comparison to an efficiency or output that would be achieved in the absence of the deploying. In at least some embodiments, the air is introduced prior to introduction to a expansion turbine within a compressed air energy storage (CAES) generating system, or preceding a recuperative heat exchanger applied at a CAES system, so as to utilize the waste heat from the data center to increase the efficiency or output of an expansion turbine in comparison to an efficiency or output that would be achieved in the absence of the deploying.

At least some aspects and/or embodiments of this disclosure are directed to a method of utilizing a renewable power source and compressed air energy storage (CAES) system, including: contemporaneously, to continuously provide for power and cooling of a data center, so that during times when the renewable source is available, the electrical output is utilized to power the data center, with a portion of the generated power operating a compressor to deliver air to the high pressure reservoir used for CAES; subsequently expanding the air to provide for cooling of the data center, said flow rate of expanded air for cooling air selected based on measurements or calculations of the real-time data center cooling requirements. In at least some embodiments, the expanded cooling air, after providing for data center cooling and containing data center waste heat, to be directed to the expansion turbine, thus augmenting power produced. In at least some embodiments, the subsequently expanding of the air is expanded by at least a critical pressure ratio.

At least some aspects and/or embodiments of this disclosure are directed to a method of utilizing a renewable power source and compressed air energy storage (CAES) system, including: contemporaneously, to continuously provide for power and cooling of a data center, so that during times when the renewable source is not available, and the CAES reservoir is at least partially charged with compressed air, and the electrical output of the CAES expansion turbine is the generating source to power the data center; subsequently a stream of high pressure air is withdrawn and expanded to provide for cooling of the data center, said flow rate of expanded air for cooling air selected based on measurements or calculations of the real-time data center cooling requirements.

At least some aspects and/or embodiments of this disclosure are directed to a method of utilizing a renewable power source and compressed air energy storage (CAES) system, including: contemporaneously, to continuously provide for power and cooling of a data center, so that during times when the renewable source is available, utilizing electrical output to power the data center, with a portion of the generated power operating a compressor to deliver air to the high pressure reservoir for CAES; subsequently expanding the air to provide for direct cooling of the data center, by expansion of a high pressure jet onto data center components, the flow rate of expanded air for cooling air selected based on measurements or calculations of the real-time data center cooling requirements. In at least some embodiments, the subsequently expanding of the air is expanded by at least a critical pressure ratio.

Other exemplary embodiments and advantages of this disclosure can be ascertained by reviewing the present disclosure and the accompanying drawings.

### BRIEF DESCRIPTION OF THE SEVERAL VIEWS OF THE DRAWING(S)

This disclosure is further described in the detailed description that follows, with reference to the drawings, in which:

FIG. 1 is a schematic of a power generation system combined with a CAES system in accordance with at least some aspects of this disclosure;

FIG. 1A is a schematic of an alternative power generation system combined with a CAES system in accordance with at least some aspects of this disclosure;

FIG. 2 illustrates a cooling air distribution network in accordance with at least some aspects of this disclosure;

FIG. 3 illustrates microprocessor cooling in accordance with at least some aspects of this disclosure;

FIG. 4 illustrates an arrangement of server components in accordance with at least some aspects of this disclosure; and

FIG. 5 illustrates a power block and ancillary equipment for indirect cooling in accordance with at least some aspects of this disclosure.

### DETAILED DESCRIPTION OF THE INVENTION

Exemplary embodiments of this disclosure are described herein by way of example.

At least some embodiments of this disclosure are directed to methods, systems, and apparatuses to exclusively or predominantly utilize renewable power from intermittent sources, such as wind or solar, to operate a data center, and to provide for both electrical power requirements as well as cooling, while enabling such operation on a twenty-four x seven basis.

At least some embodiments of this disclosure are also directed to a methods, systems, and apparatuses not (or not only) to generate but to store and maximize the utilization of such power from intermittent means such as wind or solar sources, by exploiting the process conditions to uniquely cool critical components of an array of servers and ancillary equipment, generally in the form of a data center.

At least some embodiments of this disclosure can address the continually growing consumption of power to operate data centers and generation of CO₂ emissions as a consequence of such operations. As highlighted in the August 2007 report to Congress by the U.S. Environmental Protection Agency (EPA, 2007), datacenter power consumption is rapidly growing, and will continue to do so. Accordingly, the production of CO₂ emissions due to data center operation is escalating.

The utilization of renewable power for datacenter operations is of interest, but the inability to store either renewable power from intermittent sources such as wind turbines or solar power from photovoltaic arrays can prevent the continual, “twenty-four hour×seven days a week” operation of data centers on solely renewable power. It is well documented in the EPA Report to Congress that the power required for cooling the datacenter can equal the power consumed by the servers. The utilization of compressed air energy storage (CAES) is a promising technique to store the renewable power from wind turbines or a solar array. The utilization of CAES has been studied for decades, with some of the early thermodynamic analysis demonstrating the potential benefits of the concept (see for example Fort, J. A., “A Thermodynamic Analysis of Five Compressed Air Energy Storage Cycles”, Report by the Battelle Memorial Institute for the U.S. Department of Energy under Contract DE-AC06-76RLO 1830, March, 1983.). Since that time CAES has received considerable interest as a way to store energy from renewable sources, and has recently been evaluated in detail for various sites in California (EPRI, 2008. “Compressed Air Energy Storage Scoping Study for California”, prepared for the California Energy Commission Public Interest Energy Research Program, Report CEC-500-2008-069, November, 2008).

However, a CAES system can require significant additional investment in capital that may only be utilized to generate power for a fraction of the day. Exploiting portions of a CAES system to assist in cooling a datacenter can be one way of improving the utilization of the equipment, and lowering the cost of storing renewable power.

This disclosure describes methods, systems, and apparatuses by which elements of the CAES system can both augment the task of powering a datacenter, and provide for cooling of a datacenter. Both of these ends can simultaneously be addressed by the methods, systems, and apparatuses disclosed in this disclosure.

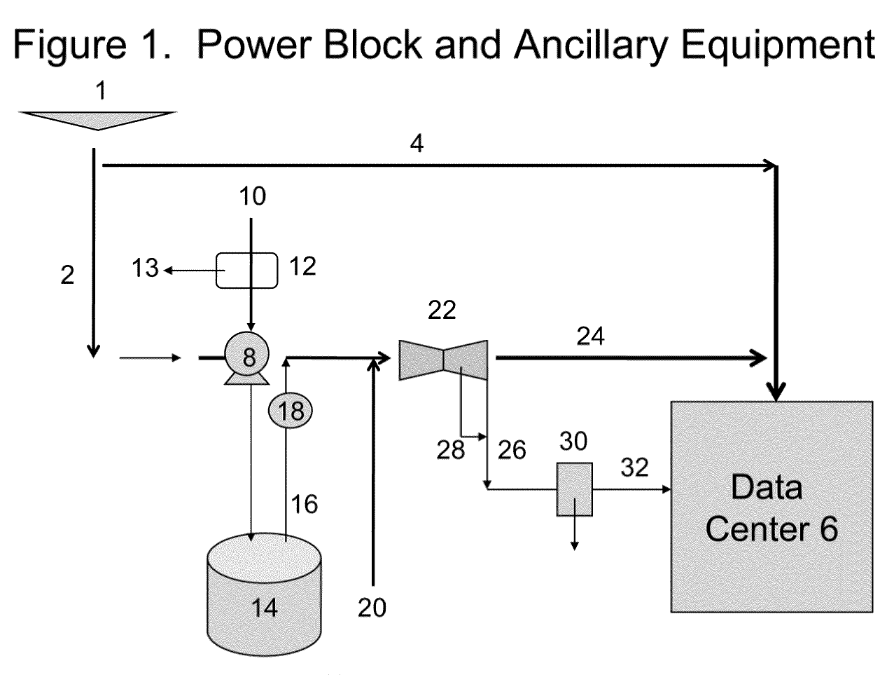

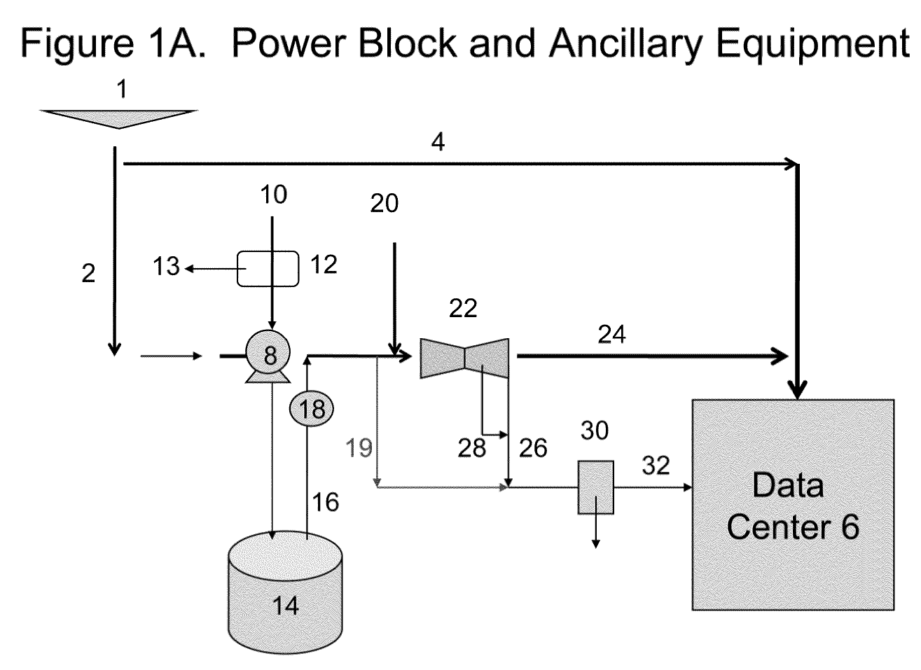

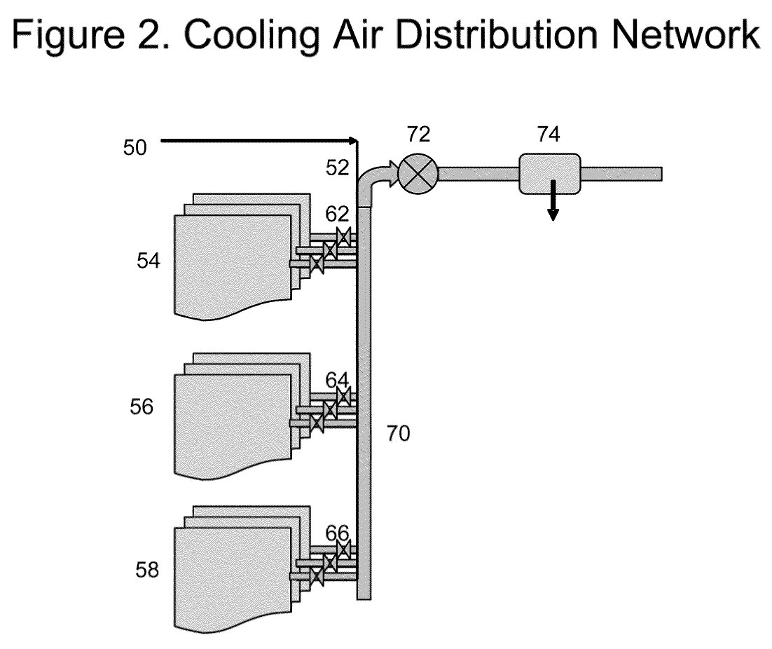

At least some of the embodiments of this disclosure can include two components: a power generation storage block or island, and an apparatus to utilize high pressure, compressed air for CAES. The latter aspect can include generation of high pressure air for energy storage, which in addition to providing for motive power in an air expansion turbine can provide a low temperature media that can be utilized to cool microprocessors and ancillary server components. This cooling method and system can contribute to the optimal or near optimal utilization of renewable power resources and storage equipment, and can provide for a near-zero or zero-CO₂ footprint to power and cool a data center. At least some embodiments of these methods, systems, and apparatuses are described in conjunction with FIG. 1 (Power Block and Ancillary Equipment), and FIG. 2 (Cooling Air Distribution Network).

FIG. 1 presents a simplified schematic of how features of a power generation system can be combined with a CAES system to contemporaneously provide a way to store power, and provide for cooling of a data center.

FIG. 1 depicts a collector of renewable energy, either wind, or in the case shown, a solar array 1, which can, for example, be a photovoltaic system, or concentrated array of solar reflectors and a radiant energy collector to raise steam, the latter for expansion in a steam turbine to generate power.

The renewable source 1 generates electrical power 2 that can drive an electrical motor to power a compressor 8 to compress air 10 from ambient sources. In actual practice, the compression step can be much more complex, as the heat generated by the compression step is usually removed. Most commercial compressors that would be used employ the concept of intercooling, where an increase in pressure by, for example, a factor of one-hundred would be carried out in two steps, each a factor of ten, with the heat of compression removed following each compression step. Accordingly, the method of intercooling a compressor step is well known, and is not depicted in FIG. 1 for simplicity.

A portion of the power generated that is generated from renewable power source 1 can be accessed to provide electrical power 4 for a datacenter 6. The renewable power source 1 can provide power for the datacenter 6 during the period when the renewable power source is available and operating, such as during the day for a solar-based system, or during times when winds are adequate for wind-driven power.

Further details of the exemplary process, system and apparatus are described below. Ambient air 10 can be ingested by the compressor, which optionally can be subject to a de-humidifier 12, such as a desiccant process, configured in a regenerative or recuperative exchanger. The utilization of a desiccant process or any other type of moisture-removing process can provide the required service to dehumidify the incoming air and thus remove water 13 from the working air.

The high pressure air from the compressor 8 can be delivered to a cavity 14 for storage, with said cavity either a man-made structure or artificial structure, or a naturally occurring geologic formation. The heat that is removed within the compressor can either be stored for subsequent use, or rejected. The quantity of compressed air that can be stored can range from short periods of time measured in hours, to longer periods measured in days.

An apparatus and/or system to control the discharge of high pressure air 16 from the storage cavity 14 can allow high pressure air to be metered by a valve, series of valves, or high pressure turboexpander 18 to allow expansion to a lower pressure, at a controlled mass flow rate into an air-driven expansion turbine 22, that can convert the high pressure air into mechanical work and then electrical power 24. This latter source of power 24 from the air-driven expansion turbine 22 can be utilized to power the servers and ancillary equipment in the data center 6 when the renewable source of power 4 is inoperable or not available. In the context of this discussion, a high pressure turboexpander is a device used to provide for cooling from the expansion of high pressure gases, and may or may not produce shaft work as a byproduct. In contrast, an air-driven expansion turbine is a device primarily intended to generate shaft work and electrical power, as a consequence of expanding a high pressure gas, and further can offer a means to accommodate added heat to improve the effectiveness of the process. Both such devices could be used in the described embodiments.

In at least some embodiments of this arrangement, supplemental heat 20 can be added to the inlet of the air-driven expansion turbine. The addition of heat can be highly beneficial, as the temperature of the compressed air after expansion from the storage cavity or vessel 14 can be lowered, in some cases significantly, simply by the act of expansion from the storage pressure to the pressure either at the entrance the air-driven expansion turbine, or to the ambient atmosphere. Depending on the ratio of pressures in the storage vessel 14 and the inlet to the air-driven expansion turbine 22, the temperature of the air upon expanding can decrease significantly. In some cases, where the compressed air is stored at extremely high pressures, the temperature of the working media air upon expansion can approach that of freezing of water, or down to sub-zero conditions, and even in some cases can approach cryogenic conditions. One manner to improve the utilization of this compressed air in deriving power in an air-driven expansion turbine can be to add heat 20, thus increasing the enthalpy of the air, improving the amount of useful work that can be obtained. In fact, this heating of the air in many cases can be extremely beneficial to derive a feasible amount of useful work from the turbine 22, as the expansion of cold, unheated air may not derive significant work. This embodiment can provide the basis for utilization with commercial CAES systems such as the unit in commercial operation at the Mcintosh Station in Alabama. The source of heat added 20 conventionally can be a fuel such as natural gas, or other fuels, or any waste source of heat.

FIG. 1 presents a simplified view of a process flowsheet of a compressed air energy storage system. There are numerous variants of how the additional heat 20 can be added to the process, prior to the expansion of air in an expansion turbine. Specifically, most commercial of CAES require firing a fuel which elevates the temperature of the gas exiting after expansion 24, and some of this heat can be used in a recuperative heat exchanger to augment a heat source 20. Under these conditions, an extraction stream of effluent 26 from the air-driven expansion turbine 22 will be at a relatively high temperature, for example several hundred degrees (F.), that can limit its use for cooling by expansion. However, there can be some applications where an interstage extraction of gas effluent 28 within the air-driven expansion turbine will be at elevated pressure of several hundred pounds per square inch (psi), and depending on the amount of heat added 20, this effluent stream 28 could be expanded and used for cooling. Note that pounds per square inch can be measured either on an absolute basis (psia), or relative to ambient pressure, as indicated by a gauge (psig)

The expanded air at elevated pressures and reduced temperatures can be accessed from any of several points in the process, for the purpose of cooling. High pressure and reduced temperature air can be extracted from any point either preceding or following the control valve or commercial expander 18, preceding or following the point of heat addition 20 (see for example the extraction of air 19 preceding the point of heat addition 20 as exemplified in FIG. 1a), the exit 26 of the air-driven expansion turbine 22, or optionally between stages 28 of expansion.

The pressure and temperature of this air is variable, but in at least some embodiments, the pressure should be adequate to deliver critical or choked flow across an orifice in a series of cooling jets, that will discharge cooling air on the surface of microprocessors in the datacenter.

Accordingly, at least in some embodiments, in order to achieve critical flow at sea level, this air can be at least 28 psia pressure (or about 13 psig), or higher to create critical or choked flow conditions, to compensate for losses within the delivery system. The actual pressure can be higher if the datacenter is operated at greater than atmospheric pressure, which is an option to increase the density of the cooling media as a method to improve heat removal, as well as provide for lower cooling temperatures.

The utilization of high pressure air for cooling under critical flow conditions, where flow is choked, is a significant departure from conventional cooling by impingement of a conventional high momentum ‘jet’ of air. This is a significant departure because such conditions can provide for expanding the air from the storage or delivery pressure to a fraction of the storage pressure, equal to the pressure at the device or surface to be cooled, resulting in lower temperature, and the ability to better control the rate of mass flow and thus the degree of cooling. Specifically, under such choked conditions, the mass rate of cooling air discharge can be constant, and affected only by the change in density of the delivery pressure. Accordingly, the utilization of flow at critical expansion or choked conditions can provide a method to control the rate at which cooling air is delivered to the source of heat to be cooled.

It can be beneficial to recognize the temperature of the expanded air from the storage cavity 14 or vessel can be very low, approaching water freezing temperatures, and even for some cases approaching cryogenic temperatures. The availability of such low temperature air can provide the opportunity to provide either direct or indirect cooling to the data center, as further described in this disclosure.

Direct Cooling

An option to provide for cooling of a datacenter or the components of a data center is to utilize the expanded but still high pressure air (e.g. at least several atmospheres) at low temperature (typically less than 60° F.) after complete or partial expansion from the storage pressure. In this manner, the expanded and cooled air can be directly applied to datacenter or server components. In this discussion, the embodiment of direct cooling can be carried out by extracting a stream of this high pressure and low temperature air at any of the locations previously identified, either before or while in the process of expansion, and utilized with a manifold to distribute said air through a datacenter to provide cooling for microprocessors and other associated equipment.

As previously described, there are numerous locations where high pressure air can be extracted from a CAES system for cooling the elements of a data center or the components of a server. FIG. 1 depicts only one example and is not meant to specify or limit the type of application. As shown in FIG. 1, the high pressure air for cooling, depicted as obtained from the exit of the air-driven expansion turbine but in fact available from any points of higher pressure, can optionally be passed through a heat exchanger 30, which adjusts the temperature of the final data center inlet cooling stream 26 so that the final temperature of the cooling air 32 that expands onto a heat sink located on any data center component can be controlled to a suitable temperature to provide cooling for, as an example, a microprocessor. Depending on the configuration of the heat removing device or heat sink, in at least some embodiments this high pressure cooling air can be discharged at less than 32° F., providing that moisture is effectively removed. However, maintaining the temperature at the discharge orifice above water freezing, in at least some embodiments, can be effective and thus the need to add heat through a heat exchanger 30 can also be effective for at least such embodiments.

FIG. 2 illustrates one possible exemplary configuration of equipment in a datacenter to enable the utilization of high pressure, compressed air for cooling the microprocessors and ancillary equipment within the servers. Compressed and optionally de-humidified and cooled air can be distributed by an array of distribution lines that can operate anywhere over a wide range of pressure, for example from 8 to 100 psig, depending on the size and layout of the server network. Compressed air at low temperature 50 following expansion from any of the locations described previously in FIG. 1 can be delivered into a distribution manifold 52, that directs said compressed air to servers connected as an array from the distribution manifold 54, 56, 58.

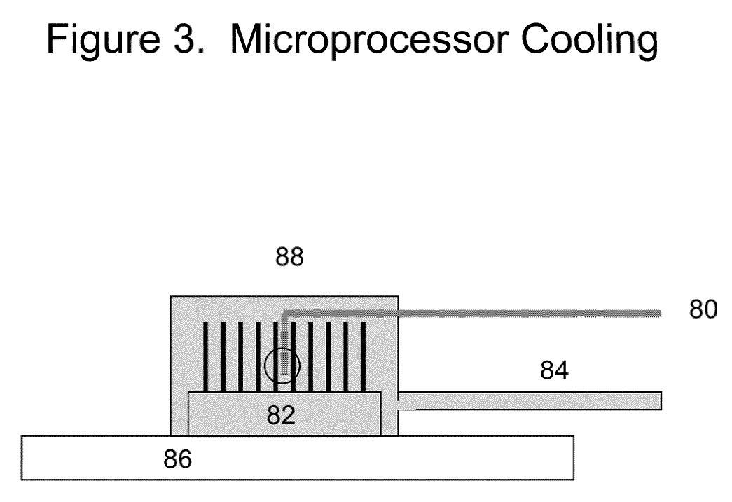

The servers receive compressed air from delivery lines with control orifices that monitor the quantity, pressure and temperature of cooling air 62, 64, 66. Optionally, the cooling apparatus located on the microprocessor can be configured with a flow shield to retain the cooling media separate from the ambient air in the data center, thus not introducing the collected heat into the ambient data center environment. There are several systems and/or apparatus by which the cooling media can be retained separate from the ambient air, all of which are compatible with the embodiments illustrated in FIG. 3.

The cooling media, once having absorbed heat from the servers, can be returned or discharged through a central plenum chamber 70. The motive force for transporting the cooling air can be residual pressure within the air distribution network, or an induced draft imposed on the plenum chamber by an induced draft fan 72. The effluent air, having removed heat from the microprocessors, will be at elevated temperature, and in at least some embodiments can transfer the contained heat through a heat exchanger 74 for other purposes. For example, this heated effluent could be utilized to provide heat to elevate the temperature of the compressed air entering the air-driven expansion turbine, and thus can represent all or partial heat input 20 as illustrated in FIG. 1.

FIG. 3 presents a schematic illustrating an exemplary method and system of utilizing the compressed, low temperature air for microprocessor cooling. The high pressure and low temperature air 80, which as described previously can be delivered at a controlled temperature that could approach and possibly be below 32° F., is directed into a heat sink that can be located on a microprocessor, configured with a geometry to disperse heat effectively. The heat sink can include of an array of pins, fins, or other geometric shapes that can assist in the extraction of heat from the microprocessor. Such heat sinks, that can be made from copper or aluminum, can be utilized to convey heat from the microprocessor.

In at least some embodiments of this disclosure, utilization of high pressure air at, for example, “critical” pressure conditions so that the ratio of the pressure following and preceding the discharge point is at a minimum 0.528 at atmospheric, sea level—thus inducing choked flow. This critical pressure ratio can be established with a specially designed orifice located at the point of gas entry into the cooling sink. As a consequence, the cooling air or gas temperature is reduced upon this expansion.

The ability to access high pressure air from the storage cavity of a CAES system, which is constructed and maintained to support the continual operation of the renewable power source, can provide a significant advantage in providing this cooling media for negligible cost.

Utilizing expanded air within a jet at or near critical pressure conditions is not known to have been previously commercially applied for microprocessor cooling and would not have been expected to be applied for at least several reasons related to the consequences of compressing air to establish the delivery pressure. The use of an air jet for cooling a microprocessor is not new, but has been exclusively used in test apparatus to evaluate the effectiveness of various designs of the cooling fins or cooling pins that are constructed as an array onto a microprocessor. Specifically, Reddy (Reddy, A. V., et. al., “Experimental and Numerical Simulation Study of Heat Sinks With Impingement Flow at High Reynolds Number”, undated paper issued by Intel Corporation) has explored numerical simulations of heat sink performance with impinging low pressure air jets, and compared data to actual experimental results. Jung (Jung, H. H., et. al, “Pin-Fin Heat Sink modeling and Characterization”, Proceedings of the Sixteenth IEEE-Semi-Therm Symposium) similarly describes an apparatus for testing the effectiveness of various arrays of pins or fins. Jung warns that using such impingement cooling is not economic, due to turbulence generated by the low pressure air jet, and the increase in air pumping power required. However, this statement, while perhaps true in the context of providing compression solely for cooling, is not necessarily true if such high pressure cooling media is a byproduct of a large system such as the ancillary equipment for CAES. Further, Dogruoz (Dogruoz, M. B. et. al., “A Model for Flow Bypass and Tip Leakage from Pin Fin heat Sinks”, Journal of electronic Packaging, March, 2006, volume 128) reports that low pressure jet impingement can be applied, but that leakage of the cooling media or some other means of bypass of cooling media is restrictive.

The key difference between cooling with low pressure impingement jets as has been studied to date, and the utilization of a jet that has been expanded from near or exceeding the critical pressure ratios as described in this disclosure, is the intensity of cooling. Specifically, the impingement jets as studied previously simply serve the purpose of convecting or transferring to the microprocessor or other device a stream of lower temperature air that has been derived from another source. For example, the source could be a plenum chamber within an air conditioning system. These studies all evaluate the heat transfer coefficient and other heat transfer variables that are responsible for the effectiveness with which the relatively low temperature air from the ancillary source serves to cool the microprocessor, or other server component of interest. The referenced sources all employ relatively low pressure by which to create the cooling jet.

The method proposed in this disclosure is different, in that the reservoir or storage pressure is approximately twice the pressure at the discharge—the latter presumably near ambient pressure. Thus, the jet can be created by at least about 28 psia (13 psig) or more pressure. As a consequence, the rapid expansion of stored air from at least 28 psia to ambient pressure can lower the gas temperature, as a consequence of Boyles Law. In this manner, the cooling can be provided by the expansion of the jet itself—the jet can do more than simply convect in cooler air provided by another source. It is the work of compression, and the heat removed by intercooling of a compressor or another manner of heat extraction, that provides the source of the cooling.

The compression step can require significant work, which consumes power. If the sole purpose of the air compression step is to provide cooling for microprocessors, there may not be any significant cost or performance advantage over conventional forced convection cooling. This is the potential barrier that was recognized by Reddy and Jung, as examples.

Further, the act of compression can elevate the temperature of the cooling air, by an amount defined for an ideal gas by Boyles Law. However, in at least some embodiments of the methods, systems, and apparatus described in this disclosure, this heat created by compression can be dissipated within the storage cavity for the CAES system, or can be collected upon compression and removed from or preceding the storage cavity, and in at least some embodiments utilized for providing heat at the inlet of the air-driven expansion turbine.

Consequently, the expansion of high pressure air across a critical orifice, or other expansion device deployed within the embodiment of the process flow sheet, can provide for microprocessor or other server component cooling. Specifically, the work of compression will already have been expended to store compressed air for the CAES to provide a reservoir for power. Referring to FIG. 1, the pressure of air at the exit 26 of the air-driven expansion turbine 22 or from a stage 28 within the turbine 22 will, in most applications, be adequate to provide critical flow conditions, and thus rapid expansion and cooling within a cooling jet. Particularly if the extraction point is at the turbine exit 26, the gas at this point in some applications can be considered fully expanded with respect to power generation, and no longer provides useful work. However, depending on whether heat 20 was added, or how much heat 20 was added, the pressure and temperature at 26 can be more than adequate to provide the critical flow conditions and thus cooling potential.

Returning to FIG. 3, the cooling air 80, now optionally at reduced temperature, can enter the heat sink 82, which optionally can be contained within a sheath 88 to retain the flow within the array of cooling pins or fins. This sheath is configured with a discharge 84 in which the heated air that extracts heat from the microprocessor 86 is evicted. This air, depending on the size of the microprocessor, can exit the cooling sheath at a temperature that can be, for example, 50-70° F., or optionally higher depending on the microprocessor configuration, which can still be low enough to effect cooling of the remaining heat-generating devices within the server—such as the memory device, or other components. Accordingly, this evicted cooling air can be directed at any of these other devices.

The configuration of servers utilized can then be equipped with the necessary distribution lines to route this cooling air into the servers. This cooling air when leaving the final server component can retain the heat from cooling, and can approach, for example, from 80° F. to 90° F. This air can be evacuated, for example with a conventional fan, but in at least some embodiments not require any direct cooling.

Alternatively, the components of the servers can be aligned so that the cooling air proceeds sequentially from the microprocessor to subsequent components for which cooling can be beneficial, and be directed into a plenum chamber for removal.

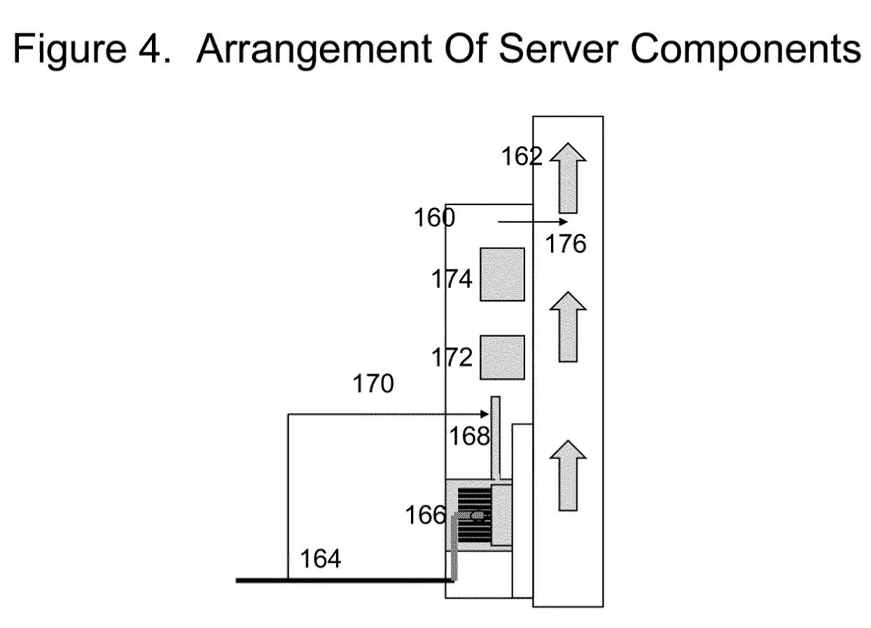

FIG. 4 depicts an example array of components within a server, in which the components are aligned vertically to take advantage of natural convection forces. Specifically, FIG. 4 shows a housing for a server 160, vertically oriented, and adjacent and in communication with a plenum chamber or evacuation duct 162. A microprocessor 166 employing the same cooling scheme shown in FIG. 3 of expanding compressed air within a jet is shown and is cooled by high pressure air 164. A small fraction of the cooling air 164 can be diverted to an alternate distribution line 170, to supplement cooling in other components. The cooling air that transits the microprocessor can exit the cooling sheath 168, which is directed to the remaining components. The temperature of cooling air at this location can be controlled by the relative amount of auxiliary cooling from auxiliary cooling stream 170.

Optionally, the cooling media once exiting the microprocessor cooling sheath 168 can be directed to other components within the server that require cooling, such as components 172 and 174. The cooling air is then evacuated into the plenum 162 by a penetration or some form of fluid communication 176, for evacuation. This embodiment can include altering the layout of the server, for example in conjunction with component technology such as flash-memory devices that do not require the degree of cooling of conventional memory devices.

An aspect of the embodiment depicted in FIG. 4 is that effluent heat from the server components can be evacuated into a plenum that can retain the rejected heat separate from the local environment, and can be discharged. Accordingly, in at least some embodiments, the ambient environment within the container or room that houses the servers will not require direct cooling. Alternatively this heat can be utilized for any of several applications, for example as described previously to preheat the air entering the air expansion compressor in a CAES system.

The preceding examples are presented only as a manner of communicating the types of embodiments possible, to improve and, in at least some embodiments maximize, the utilization of renewable power generation sources in providing electrical power to operate a data center, and exploit byproduct media from the process for cooling. The arrangements depicted in this disclosure are not meant to restrict the application in any way.

In at least some embodiments, to increase the ability of the expanded air to cool the microprocessors, the entire datacenter can be operated at elevated pressure, to increase the density of the air and thus increase the ability to remove heat. Also, the expansion of pressure of the cooling media at the orifice can be configured to freeze suspended water droplets that condense from residual humidity in the air, which can then provide an additional means to absorb heat and be volatilized.

FIG. 1 depicts a solar array as the source of interruptible renewable power, but wind turbines could provide the same power generation characteristics.

Indirect cooling

The concept of utilizing CAES as a method, system, and/or apparatus to store renewable power from wind or solar sources can support the indirect cooling of a datacenter. In this application, indirect cooling methods and apparatus can remove the heat from the servers from where it can be transferred to a heat exchanger, that communicates by air, other gaseous, or liquid media with the low temperature air generated by the expansion of compressed air. The low temperature air that can provide for cooling can be accessed at any point of partial or complete expansion of the compressed air that can communicate with a heat exchanger to provide cooling for a datacenter.

In at least some embodiments, a commercial emergency back-up system can be utilized with compressed air to generate emergency power for short periods of time, and can apply the low temperature effluent from an unheated expansion turbine to provide emergency cooling. The CoolAirDC device produced by Active Power device employs a small reservoir built within or adjacent to a data center for compressed air, and includes among other components an expansion turbine that can generate power for brief periods (e.g. limited to several minutes) to provide for back-up power in the event of an emergency. This concept applies the expanded effluent from the air expansion turbine to generate cool air, again for brief periods of time, such as several minutes. However, the concept described does not integrate the heat balance of the data center with that on the emergency generator—which could have been done to provide for preheat of the high pressure air preceding the small turbine, possibly reducing start-up time and increasing power output.

The concept proposed in this disclosure purposely integrates the data center heat balance with that of the CAES system, and the air-driven expansion turbine, to improve performance. Specifically, the concept proposed in this disclosure provides for cooling of the data center by expanding air from the storage reservoir in transit to, and thus preceding the inlet of the air-driven expansion turbine. The air withdrawn from the air expansion inlet is returned, now at higher temperature, to the same location. As a consequence, this methodology recycles or returns the data center waste heat to the power generation process, contributing to the expansion turbine power output or thermal efficiency.

In this variant, the datacenter servers do not necessarily have to employ the air distribution manifold for cooling air described in FIGS. 2 and 3, but can be of conventional design. By conventional design, this refers to either the standard datacenter racks that employ cooling air that is distributed below the floor, or the modular-type data centers that are configured in shipping containers, such as the Ice Cube concept introduced by SGI, and others cooled by water or air.

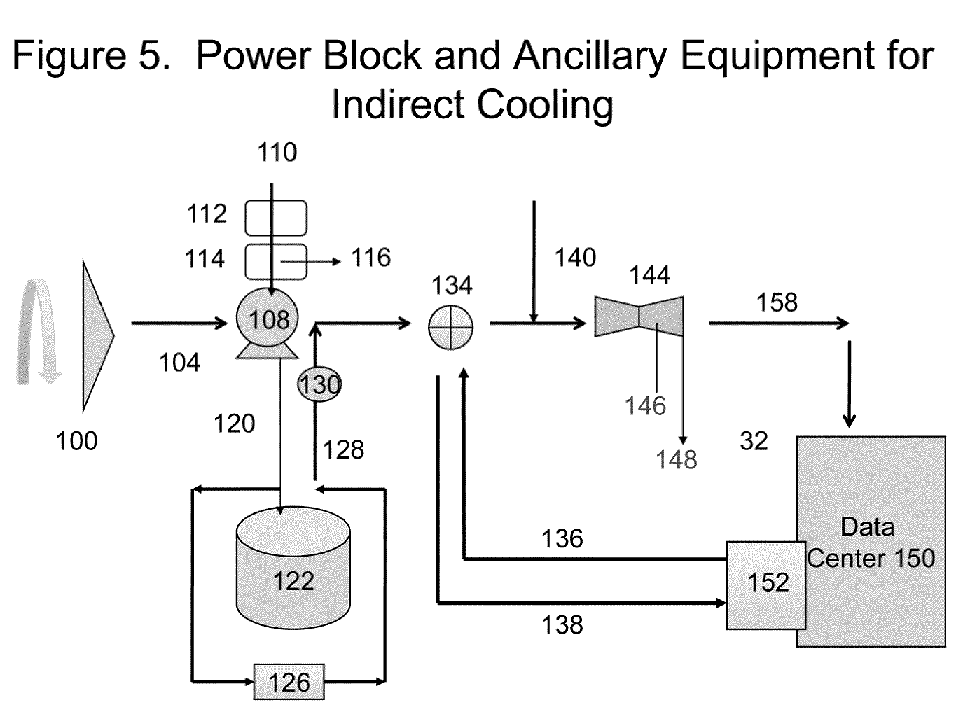

FIG. 5 presents a variant of this embodiment that describes the indirect cooling method. In this example, a wind turbine 100 is utilized as the source of renewable power. The wind turbine drives a generator that is utilized to directly power the datacenter 150, an arrangement that is not shown in FIG. 5 but is analogous to the arrangement of power delivered to the datacenter depicted in FIG. 1. The wind turbine 100 provides work into a shaft 104 that drives an air compressor 108. The compressor 108 ingests air 110 from the ambient, which is optionally filtered for example at a filter 112, and subjected to a dehumidification process for example in dehumidifier 114 in which condensed water 116 is withdrawn, for example utilizing a chemical desiccant or other moisture removing process and/or apparatus.

As a consequence of the compression process, high pressure air 120 is pumped into a storage cavity 122, that can be, for example, either a series of man made or artificial vessels, or lengths of pipes, or natural caverns or other naturally occurring structures such as salt domes that can store large quantities of high pressure, compressed air.

The pressure to which air is compressed can, for example, range from several atmospheres to several hundred atmospheres. The artificial vessel or natural structure 122 is utilized to store the work of compression into the cavern or man made device, and extracted upon demand. The demand for compressed air 128 is controlled by a valve 130, which expands the air for use in an air-driven expansion turbine 144. As discussed in FIGS. 1 and 1A, depending on whether heat 140 is added preceding the air expansion turbine, effluent stream can be withdrawn from the exit of the expansion turbine 148 or from within the air expansion turbine 146 to augment cooling. Depending on the ratio of pressures in the storage vessel 122 and the inlet to the air-driven expansion turbine 144, the temperature of the air upon expansion can decrease. Analogous to FIG. 1, the electrical power 158 that is generated by the expansion turbine 144 is used to power the data center 150.

As described previously, in some cases, where the containment of compressed air is at extremely high pressures, the temperature of the working media air upon expansion can approach the freezing of water, or be reduced to sub-zero conditions, and even in some cases can approach cryogenic conditions. Also as discussed previously, one practical way to improve the utilization of this compressed air within an air-driven expansion turbine can be to add heat 140, thus increasing the enthalpy of the air, improving the amount of useful work that can be obtained by expansion in a compressed air turbine.

As described previously, the heating of the air in many cases can be important to extracting a feasible amount of useful work, and can provide the basis for commercial CAES systems. The source of heat conventionally can be a fuel such as natural gas, or other fuels, or any waste source of heat. The location of where the source of heat is added to the process as exemplified in FIG. 5 is immediately preceding the expansion turbine, but this heat can be added at any point following the expansion from the storage cavity or vessel 122.

FIG. 5 also illustrates an optional scheme to transfer heat generated by the compression of air by the compressor 108 into a storage media, for transfer to the air when it is expanded from the storage vessel 122. As described previously, the act of compression can elevate the temperature of the compressed air, and this additional heat generated by the work of compression can be recovered in commercial compressors. After compression by the compressor 108, heat can be withdrawn by any number of methods and/or apparatus such as a conventional heat exchanger, and stored in a thermal storage device 126. The thermal storage device can be of any type of classification that will store heat. This heat can be delivered after expansion at any location, to supplement the enthalpy of the air as it enters the expander. The location of heat addition on FIG. 5 is shown only for example, and the actual location of heat addition could be at any point before the inlet of the air-driven expansion turbine.

The low temperature of the expanded gas from the storage vessel 122—even if increased from subzero temperatures by the thermal storage device 126—can still be of a temperature suitable for cooling a data center 150. In the example case shown, the datacenter utilizes a heat exchanger 152 to cool the servers, either based on circulating air, or circulating water within the data center. The manner and specifics of how the heat is extracted from the microprocessors can vary in various aspects and embodiments of this disclosure—for example, conventional servers that access cooled air distributed under the floor are possible; the water-based systems as deployed by the SGI IceCube concept, or even the direct utilization of water to cool individual microprocessors. Regardless of how the heat from the servers and ancillary components is withdrawn, a heat exchanger 152 that interfaces between the data center and the environment can be utilized to process either air or water as the cooling media.

For example, heat can be generated by the datacenter and transported from the heat exchanger—either carried by water or higher temperature air—as stream 136, and can be directed to the expanded, low temperature, but still high pressure air. A second heat exchanger 134 can accept heat from media stream 136 that was transferred from the heat exchanger 152. The data center cooling media that is cooled by the heat exchanger 134—either the air or water 138—can return to the heat exchanger 152, thus providing cooling for datacenter.

Of greater importance, and as noted previously, the process arrangement in FIG. 5 not only cools the data center 150, but provides a means by which to return the data center waste heat 136 to increase the effectiveness of the air-driven expansion turbine 144. This approach of returning this heat to augment power production provides a decided advantage, over simply using the effluent at the exit of the air-driven expansion turbine for data center cooling, as applied for short-term emergency needs. Consequently, the data center waste heat 136 contributes to power generation 158 from a CAES system.

The exemplary embodiment illustrated in FIG. 5 can provide the basis to describe the potential to utilize the low temperature air from expansion in a CAES to cool a datacenter. The benefit of this embodiment is that the equipment and operating requirements to provide for high pressure air for cooling is inherent to a CAES system. Accordingly, the cost of this approach, when integrated with CAES hardware, can be less than providing for such equipment alone for the purpose of cooling.

System Operation: Indirect Cooling

The process arrangement and equipment described in this disclosure can be used in an operating scheme that maximizes the use of renewable power to both power, and provide for indirect cooling of a data center, as in FIG. 5. The various operating strategies described can be used in an integrated manner to maximize the usefulness of the equipment. FIG. 5 can be used to describe how a CAES system and the ancillary components can be utilized to both power and cool a data center.

As an example, when the source of renewable power from a wind turbine 100 is available, the power from this renewable source would be used to directly power the data center 150. If the wind turbines exclusively drive generators that produce power, the data center will require cooling.

The cooling step will be provided by expanding compressed air, enabled by using the CAES equipment. Specifically, work from the wind turbine, either direct shaft work or electrical power would drive the compressor 108, which compresses ambient air 110 and can be treated and stored in a reservoir 122. The high pressure stored air is withdrawn 128 and is expanded through a valve or series of valves 130 or other high pressure turboexpander and transits through a heat exchanger 134, which is utilized to provide cooling for the data center 150. The data center 150 can be cooled in the manner described previously, for example by communicating with the heat exchanger 152 through media 136 and 138. This application simply requires the mass flow rate of air expanded 128 to be controlled by an expansion valve 130 or other high pressure turboexpander and thus lowered in pressure and temperature, with the mass rate of expanded air controlled by the cooling requirements of the data center. However, rather than discharge the stream of compressed air that now contains data center waste heat, this effluent can be expanded through the air-driven expansion turbine 144 to augment the output of power 158. In this manner, the data center is powered directly from the renewable source power 100, while the equipment to support CAES is used as the exclusive means of providing for data center cooling, and the waste heat is used to augment power generation.

During times when there is no renewable source of power available, the CAES system can be operated as previously described. The utilization of these two modes alternatively, as the availability of renewable energy sources allows, can provide for a data center to operate while assisting in the production and utilization of renewable power.

System Operation: Direct Cooling

In the same manner, the processes described in previously for direct cooling with a high pressure air jet can be utilized to alternatively power and cool a data center. During periods when the renewable power source from either wind turbines or solar energy are available, the power produced can directly power the data center. The cooling can be provided by a portion of the power generated utilized to operate a compressor, as shown in FIG. 1, with ambient air pressurized by compressor 8 and stored in a reservoir 14. A portion of the storage, high pressure air can be extracted 16 and controlled by a valve 18. The effluent of the valve 18 or high pressure turboexpander can thereafter be directed to the data center 6 for direct cooling, for example as previously described with regard to FIGS. 2, 3, and 4.

The foregoing exemplary embodiments have been provided for the purpose of explanation and are in no way to be construed as limiting this disclosure. This disclosure is not limited to the particulars disclosed herein, but extends to all embodiments within the scope of the appended claims, and any equivalents thereof.

1. A method of cooling a data center, comprising:
extracting compressed air from a storage vessel or process stream,
expanding the air to lower a pressure of the air, with the ratio of a pressure of the air after expansion to the pressure of air before expansion being the critical pressure ratio, defining choked flow, providing a constant mass rate of cooling air, thus lowering a temperature of the air; and
dispersing the expanded air through a heat sink onto a microprocessor or other heat generating component of a server or a storage device, thus cooling the microprocessor or the other heat generating component of the server or the storage device.

2. The method of claim 1, wherein the compressed air is extracted from a compressed air energy storage vessel.

3. The method of claim 1, wherein
a ratio of the pressure to which the air is expanded, compared to delivery pressure prior to expansion, is equal to a critical pressure defining choked flow, said expansion providing choked flow, thereby providing a temperature of expanded cooling media of from 0° F. to 90° F., as delivered to a device to be cooled, and providing a constant mass rate of cooling air.

4. The method of claim 3, wherein the cooling air after expansion is retained separate from ambient air within a sheath or plenum that encompasses a component being cooled, thus eliminating cooling air bypass or leakage from the heat sink, with such cooling air subsequently discharged.

5. The method of claim 1, wherein the air after expansion onto a component to be cooled is retained separate from ambient air within a sheath or plenum that encompasses a component being cooled, thus eliminating cooling air bypass or leakage from the heat sink, with such cooling air subsequently discharged.

6. The method of claim 4, wherein the effluent air from the cooling sheath or plenum located on the component is at a temperature of 90° F. or less and provides cooling for other of a server or storage device components is directed to a central evacuation chamber, and is thereafter removed from the data center.

7. The method of claim 5, wherein the effluent air from the cooling sheath or plenum located on the component is at a temperature of 90° F. or less; and the method further comprising: the air providing cooling for other of a server or storage device components, the air thereafter directed to a central evacuation chamber, and the air thereafter removed from the data center.

8. The method of claim 4, wherein waste heat contained in the air after providing for cooling of the various components of a server or data center, is applied to provide for preheat of stored air after expansion and preceding an inlet of an expansion turbine of a compressed air energy storage system.

9. The method of claim 5, wherein waste heat contained in the air after providing for cooling of the various components of a server or data center, is applied to provide for preheat of stored air after expansion and preceding an inlet of an expansion turbine of a compressed air energy storage system.

10. A method of cooling a data center, comprising:
extracting a stream of high pressure air stored within a reservoir for a compressed air energy storage (CAES) system,
reducing pressure of the air to near atmospheric and lowering the temperature of air as it enters a heat exchanger, so that the temperature upon entry to the heat exchanger is from 0° F. to 80° F.,
passing the air through the heat exchanger that is configured to remove heat from a data center, the stream of air thereafter containing data center waste heat that is returned to the inlet of the expansion turbine.

11. The method of claim 10, further comprising:
providing an expansion of cooling air from the CAES reservoir such that a ratio of air pressure after expansion to the pressure before expansion is a critical pressure ratio to establish choked flow and to provide cooling of the data center, said stream of cooling air thereafter containing data center waste heat that is returned to the inlet of the expansion turbine.

12. A method of utilizing waste heat from a data center, comprising:
deploying the waste heat from the data center to preheat expanded gas extracted from a compressed air energy storage (CAES) reservoir prior to introduction to a expansion turbine within a CAES generating system, so as to utilize the waste heat from the data center to increase efficiency or output of an expansion turbine in comparison to an efficiency or output that would be achieved in the absence of the deploying.

13. The method claim 12, wherein the air is introduced prior to introduction to a expansion turbine within a compressed air energy storage (CAES) generating system, or preceding a recuperative heat exchanger applied at a CAES system, so as to utilize the waste heat from the data center to increase the efficiency or output of an expansion turbine in comparison to an efficiency or output that would be achieved in the absence of the deploying.

14. A method of utilizing a renewable power source and compressed air energy storage (CAES) system, comprising:
contemporaneously, to continuously provide for power and cooling of a data center, so that during times when the renewable source is available, the electrical output is utilized to power the data center, with a portion of the generated power operating a compressor to deliver air to the high pressure reservoir used for CAES;
subsequently expanding the air to provide for cooling of the data center, said flow rate of expanded air for cooling air selected based on measurements or calculations of the real-time data center cooling requirements.

15. The method of claim 14, wherein with the expanded cooling air, after providing for data center cooling and containing data center waste heat, to be directed to the expansion turbine, thus augmenting power produced.

16. The method of claim 14, wherein the subsequently expanding of the air is expanded by at least a critical pressure ratio.

17. A method of utilizing a renewable power source and compressed air energy storage (CAES) system, comprising:
contemporaneously, to continuously provide for power and cooling of a data center, so that during times when the renewable source is not available, and the electrical output of the CAES expansion turbine is the source of to power the data center, a portion of the compressed air that resides in the reservoir is extracted for cooling the data center;
subsequently expanding the air to provide for cooling of the data center, said flow rate of expanded air for cooling air selected based on measurements or calculations of the real-time data center cooling requirements.

18. The method of claim 17, wherein with the expanded cooling air, after providing for data center cooling and containing data center waste heat, the air is directed to the expansion turbine to augment power.

19. A method of utilizing a renewable power source and compressed air energy storage (CAES) system, comprising:
contemporaneously, to continuously provide for power and cooling of a data center, so that during times when the renewable source is available, utilizing electrical output to power the data center, with a portion of the generated power operating a compressor to deliver air to the high pressure reservoir for CAES;
subsequently expanding the air to provide for direct cooling of the data center, by expansion of a high pressure jet onto data center components, the flow rate of expanded air for cooling air selected based on measurements or calculations of the real-time data center cooling requirements.

20. The method of claim 19, wherein the subsequently expanding of the air is expanded by at least a critical pressure ratio.
